(19) United States
(12) Patent Application Publication
(10) Pub. No.: US 2026/0240019 A1
(43) Pub. Date: Aug. 13, 2026

(54) SEMICONDUCTOR PACKAGE

(71) Applicant: SAMSUNG ELECTRONICS CO., LTD., Suwon-si (KR)

(72) Inventors: Kiwon BAEK, Suwon-si (KR); Byeonguk JEON, Suwon-si (KR); Kihong JEONG, Suwon-si (KR)

(73) Assignee: SAMSUNG ELECTRONICS CO., LTD., Suwon-si (KR)

(21) Appl. No.: 19/319,153

(22) Filed: Sep. 4, 2025

(30) Foreign Application Priority Data
Feb. 10, 2025 (KR) 10-2025-0016518

(51) Int. Cl. H10W 70/68; H10B 80/00; H10D 80/30; H10W 70/60; H10W 70/654; H10W 74/01; H10W 74/10; H10W 74/15; H10W 90/00; H10W 90/10; H10W 90/24

(52) U.S. Cl. CPC H10W 70/68; H10W 70/611; H10W 70/654; H10W 74/012; H10W 74/117; H10W 74/15; H10W 90/10; H10W 90/24; H10W 90/724; H10W 90/752; H10W 90/754; H10B 80/00; H10D 80/30

(57) ABSTRACT

A semiconductor package includes a substrate having a first side and a second side, the substrate including pads and a solder mask layer, the pads including upper pads, a solder resist layer on the solder mask layer, a first chip structure on the solder resist layer, a second chip structure on the solder resist, a controller including connection pads, connection structures electrically connecting the connection pads and the upper pads, and an underfill portion filling a space between a side surface of the controller, a side surface of the solder resist layer, and a side surface of the solder mask layer. The solder resist layer and the solder mask layer have a center open region. A distance between the first chip structure and the second chip structure is 1 to 1.2 times a distance between the side surfaces of the solder resist layer.

### CROSS-REFERENCE TO RELATED APPLICATION(S)

This application claims priority to Korean Patent Application No. 10-2025-0016518 filed on Feb. 10, 2025 in the Korean Intellectual Property Office, the disclosure of which is incorporated by reference herein in its entirety.

### BACKGROUND

The present disclosure relates to a semiconductor package.

Recently, there has been a demand for semiconductor packages mounted in electronic devices to be smaller in size and to have high reliability. In response, semiconductor packages, including a plurality of semiconductor chips and a control chip controlling the operation of the semiconductor chips, have been developed.

### SUMMARY

One or more embodiments of the present disclosure provide a semiconductor package that may have a reduced size and improved reliability.

According to an aspect of the disclosure, a semiconductor package includes: a substrate having a first side and a second side opposing each other, wherein the substrate includes pads and a solder mask layer exposing the pads at an upper portion of the substrate, and the pads include first bonding pads adjacent the first side, second bonding pads adjacent to the second side, and upper pads between the first bonding pads and the second bonding pads; a solder resist layer on the solder mask layer; a first chip structure on the solder resist layer adjacent to the first side, the first chip structure electrically connected to the first bonding pads; a second chip structure on the solder resist layer adjacent to the second side, the second chip structure electrically connected to the second bonding pads; a controller between the first chip structure and the second chip structure, the controller including connection pads at a lower portion of the controller; connection structures electrically connecting the connection pads and the upper pads to each other; and an underfill portion surrounding a portion of each of the connection structures, between the controller and the substrate, the underfill portion filling a space defined by a side surface of the controller, a side surface of the solder resist layer, and a side surface of the solder mask layer, wherein the solder resist layer and the solder mask layer have a center open region exposing the upper pads, and a distance between the first chip structure and the second chip structure is about 1 to about 1.2 times a distance between inner side surfaces of the solder resist layer defining the center open region.

According to an aspect of the disclosure, a semiconductor package includes: a substrate having a first side and a second side opposing each other, the substrate including edge pads, center pads, and openings exposing the edge pads and the center pads; a solder resist layer on the solder mask layer and including an open region exposing the edge pads; a controller having an active surface opposing the center pads and an inactive surface opposite to the active surface, the controller including connection pads on the active surface; connection structures between the controller and the center pads of the substrate, the connection structures electrically connecting the connection pads of the controller and the center pads of the substrate to each other; at least one chip structure on the solder resist layer and spaced apart from the controller, the at least one chip structure including upper pads electrically connected to the edge pads; and an underfill portion surrounding a portion of each of the connection structures, between the controller and the substrate, the underfill portion filling a space defined by a side surface of the controller, a side surface of the solder resist layer, and a side surface of the solder mask layer, wherein the solder resist layer includes a first region surrounding a portion of the side surface of the controller, and a second region extending to at least one side of the first region, the second region corresponding to a lower area of the at least one chip structure.

According to an aspect of the disclosure, a semiconductor package includes: a substrate including edge pads and center pads on an upper portion thereof; a first solder resist layer on the substrate, the first solder resist layer exposing the edge pads and the center pads; a second solder resist layer on the first solder resist layer, the second solder resist layer having a step portion with respect to the first solder resist layer; a controller overlapping the center pads of the substrate in a vertical direction, the controller including connection pads at a lower portion of the controller; at least one pair of chip structures on the second solder resist layer and spaced apart from each other with the controller interposed therebetween, the at least one pair of chip structures including a plurality of semiconductor chips further including upper semiconductor chips on a lowermost semiconductor chip, and upper pads at upper surfaces of the at least one pair of chip structures; connection structures electrically connecting the connection pads of the controller and the center pads of the substrate to each other; a bonding wire structure electrically connecting the upper pads of each of the at least one pair of chip structures and the edge pads of the substrate to each other; and an underfill portion surrounding a portion of each of the connection structures, between the controller and the substrate, the underfill portion filling a space defined by a side surface of the controller, a side surface of the first solder resist layer, and, of the second solder resist layer, wherein the at least one pair of chip structures overlaps at least a portion of each of the first solder resist layer and the second solder resist layer in the vertical direction, and the upper semiconductor chips overlap at least a portion of the controller in the vertical direction.

### BRIEF DESCRIPTION OF THE DRAWINGS

The above and other aspects, features, and advantages of embodiments of the disclosure will be more clearly understood from the following detailed description, taken in conjunction with the accompanying drawings, in which:

FIG. 1 is a schematic plan view of a semiconductor package according to an example embodiment;

FIG. 2A is a schematic cross-sectional view of a semiconductor package according to an example embodiment;

FIG. 2B is a schematic cross-sectional view of a semiconductor package according to an example embodiment;

FIG. 3A is a schematic plan view of a semiconductor package according to embodiments.

FIG. 3B is a schematic cross-sectional view of a semiconductor package according to embodiments.

FIG. 4 is a schematic cross-sectional view of a semiconductor package according to an example embodiment;

FIG. 5 is a schematic cross-sectional view of a semiconductor package according to an example embodiment;

FIG. 6 is a schematic cross-sectional view of a semiconductor package according to an example embodiment; and

FIGS. 7A, 7B, 7C, and 7D are schematic cross-sectional views of a method of manufacturing a semiconductor package according to example embodiments.

### DETAILED DESCRIPTION

Hereinafter, example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

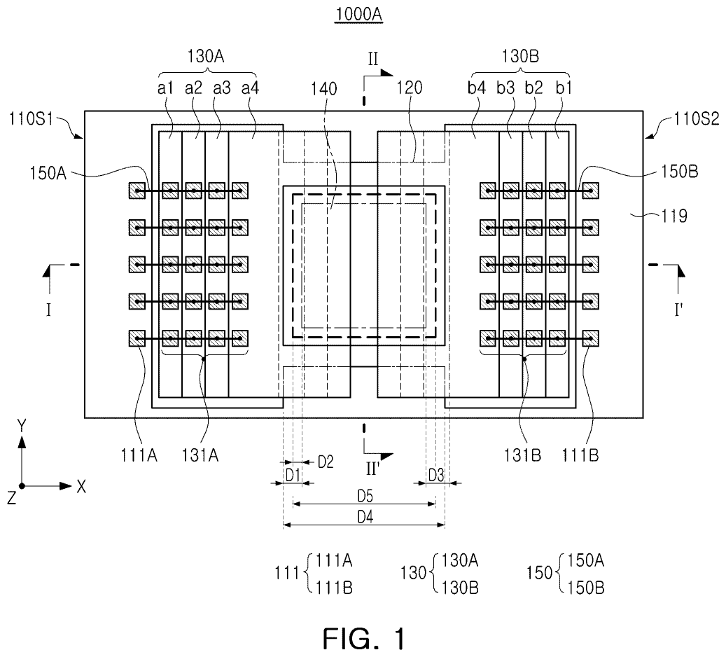

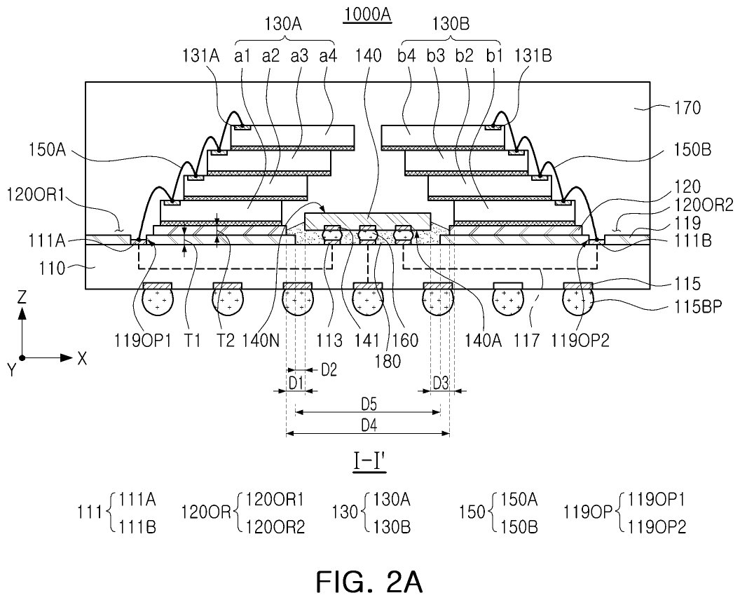

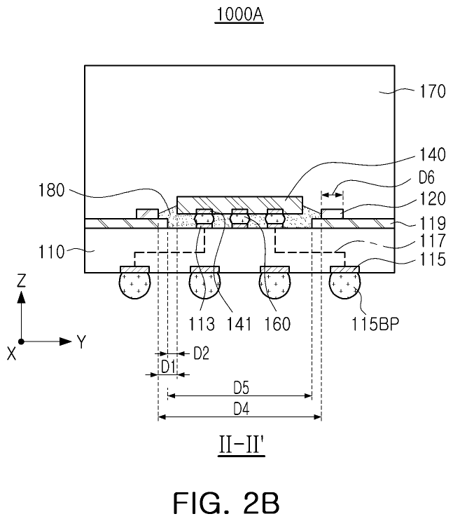

FIG. 1 is a schematic plan view of a semiconductor package 1000A according to an example embodiment. FIG. 2A is a schematic cross-sectional view of the semiconductor package 1000A according to an example embodiment. FIG. 2A is a cross-sectional view taken along line I-I′ of FIG. 1. FIG. 2B is a schematic cross-sectional view of the semiconductor package 1000A according to an example embodiment. FIG. 2B is a cross-sectional view taken along line II-II′ of FIG. 1.

Referring to FIGS. 1, 2A, and 2B, the semiconductor package 1000A according to an example embodiment may include a substrate 110, a solder resist layer 120, at least one pair of chip structures 130, a controller 140, bonding wire structures 150, connection structures 160, and an underfill portion 180. The semiconductor package 1000A may further include an encapsulant 170 encapsulating the solder resist layer 120, the at least one pair of chip structures 130, the controller 140, and the underfill portion 180, on the substrate 110.

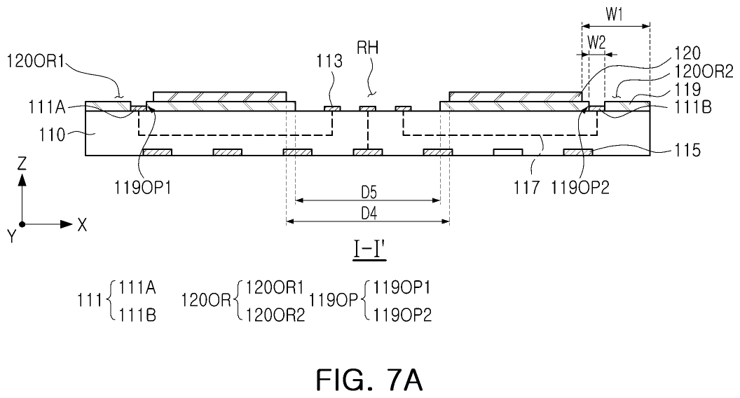

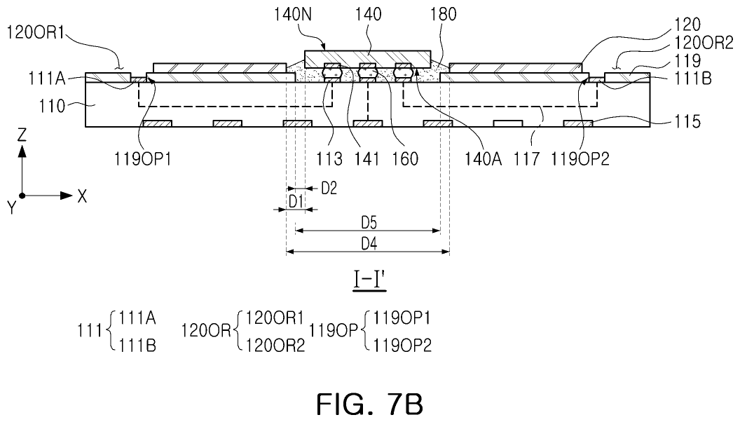

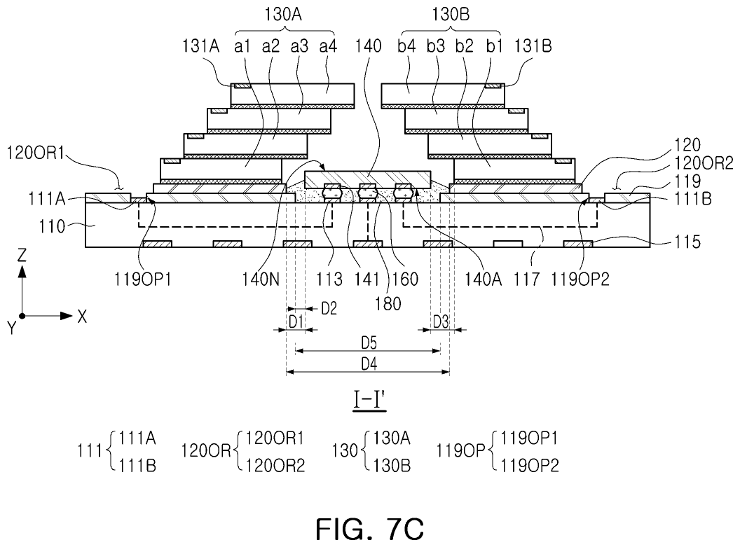

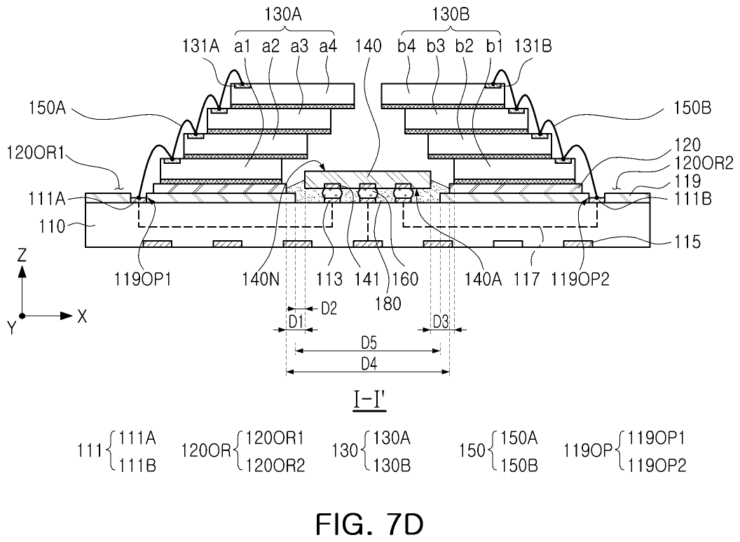

According to the disclosure, a dam structure for preventing a flow of the underfill portion 180 may be formed by forming a center open region RH (see FIG. 7A) in the solder resist layer 120 and a passivation layer 119. A controller 140 and an underfill portion 180 may be disposed in the center open region RH. Accordingly, the flow of the underfill portion 180 may be controlled, thereby resolving an issue in which the underfill portion 180 comes into contact with the at least one pair of chip structures 130, and improving the reliability of the semiconductor package 1000A.

When a dam structure is formed of the solder resist layer 120 without mounting a chip structure on the solder resist layer 120, a distance between the dam structure and at least one pair of chip structures 130 may be required, and thus a size of a semiconductor package may increase. In one or more embodiments the disclosure, the at least one pair of chip structures 130 may be disposed on the solder resist layer 120, thereby reducing a chip-mounting area and reducing a size of the semiconductor package 1000A.

Hereinafter, respective components of the semiconductor package 1000A will be described in detail.

The substrate 110 may be a semiconductor package substrate including a printed circuit board (PCB), a ceramic substrate, a glass substrate, a tape interconnection substrate, or the like. For example, the substrate 110 may be a double-sided PCB or a multilayer PCB.

The substrate 110 may have a first side 110S1 and a second side 110S2 opposing each other in a first direction, for example, an X-direction. The substrate 110 may include bonding pads 111 and upper pads 113 disposed on an upper portion thereof, bump pads 115 disposed on a lower portion thereof, and interconnection circuits 117 electrically connecting the bonding pads 111, the upper pads 113, and the bump pads 115 to each other.

The bonding pads 111, the upper pads 113, and the bump pads 115 may include, for example, at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

Connection bumps 115BP may be disposed on lower portions of the bump pads 115. The connection bumps 115BP may be formed of a conductive material having a shape such as a ball, a pin, or the like. The connection bumps 115BP may include, for example, tin (Sn) or an alloy including tin (Sn). The connection bumps 115BP may be electrically connected to an external device such as a module substrate, a system board, or the like.

The bonding pads 111 (or “edge pads”) may be disposed adjacent to edges of the substrate 110 that are spaced apart from each other in the first direction, for example, an X-direction, and may be arranged in a second direction, intersecting the first direction, for example, a Y-direction. The bonding pads 111 may include first bonding pads 111A and second bonding pads 111B. The first bonding pads 111A and the second bonding pads 111B may be adjacent to edges of the substrate 110 spaced apart from each other in the first direction (X-direction), and may be arranged in the second direction (Y-direction). For example, the first bonding pads 111A may be arranged in the second direction (Y-direction) between the first side 110S1 and a first chip structure 130A of the at least one pair of chip structures 130, and the second bonding pads 111B may be arranged in the second direction (Y-direction) between the second side 110S2 and a second chip structure 130B of the at least one pair of chip structures 130. Each of the first bonding pads 111A and the second bonding pads 111B may be electrically connected to the upper pads 113 through at least one of the interconnection circuits 117 of the substrate 110. The first bonding pads 111A and the second bonding pads 111B may be electrically connected to the bump pads 115 through the interconnection circuits 117. A metal pad layer may be additionally disposed on the bonding pads 111 and the upper pads 113. The metal pad layer may include nickel (Ni), gold (Au), or a combination thereof.

The upper pads 113 (or “center pads”) may be disposed between the first bonding pads 111A and the second bonding pads 111B. The upper pads 113 may be electrically connected to connection pads 141, disposed on a lower portion of the controller 140, through a connection structure 160. At least a portion of the upper pads 113 may be electrically connected to the bump pads 115, disposed on a lower portion of the substrate 110, through at least one of the interconnection circuits 117.

The substrate 110 may further include a passivation layer 119 (or a “solder mask layer”), disposed on the upper portion and the lower portion thereof. The passivation layer 119, disposed on the upper portion of the substrate 110, may protect the bonding pads 111 and the upper pads 113, disposed on the upper portion of the substrate 110. For example, the passivation layer 119 may protect a metal (for example, copper) included in the bonding pads 111 or the upper pads 113 from being corroded.

The passivation layer 119, disposed on the upper portion of the substrate 110, may include openings 119OP exposing upper surfaces of the bonding pads 111. The openings 119OP may include first openings 119OP1 exposing upper surfaces of the first bonding pads 111A, the first openings 119OP1 being adjacent to the first side 110S1, and second openings 119OP2 exposing upper surfaces of the second bonding pads 111B, the second openings 119OP2 being adjacent to the second side 110S2.

The passivation layer 119 may include a solder resist including an epoxy resin or a polyurethane resin, but embodiments of the disclosure are not limited thereto. For example, the passivation layer 119 may include a photoimageable solder resist (PSR) including a photoimageable resin composition. In this case, the passivation layer 119 may be referred to as a solder mask layer (or a “first solder resist layer”). The solder mask layer 119 may be formed using a screen-printing method, a roll coating method, a curtain cotton method, and a spraying method, but embodiments of the disclosure are not limited thereto. For example, when the solder resist is a dry film, the solder mask layer 119 may be formed using a film lamination method.

The solder resist layer 120 may be disposed on the passivation layer 119, and may have a step portion with respect to the passivation layer 119. The at least one pair of chip structures 130 may be disposed on the solder resist layer 120. A size and shape of the solder resist layer 120 may vary depending on the at least one pair of chip structures 130 to be disposed thereon. For example, the size and shape of the solder resist layer 120 may vary depending on a size and shape of a lower surface of each of the at least one pair of chip structures 130. The solder resist layer 120 may overlap at least a portion of each of the first chip structure 130A and the second chip structure 130B in a vertical direction. The controller 140 may overlap at least a portion of each of the first chip structure 130A and the second chip structure 130B in the vertical direction.

A thickness of the solder resist layer 120 may be within a range of about 10 μm to about 18 μm, and a thickness of the solder mask layer 119 may be within a range of about 10 μm to about 18 μm. The at least one pair of chip structures 130, spaced apart from each other in the first direction (X-direction), may be disposed on the solder resist layer 120 with the controller 140 interposed therebetween.

The solder resist layer 120 may be disposed to expose the openings 119OP in a third direction, for example, in a Z-direction. The solder resist layer 120 may include open regions 120OR exposing the first and second openings 119OP1 and 119OP2. The open regions 120OR may include first open regions 120OR1 exposing the first openings 119OP1, the first open regions 120OR1 being adjacent to the first side 110S1, and second open regions 120OR2 exposing the second openings 119OP2, the second open regions 120OR2 being adjacent to the second side 110S2. For example, the open regions 120OR may be formed on the passivation layer 119 to surround the solder resist layer 120.

Here, the open regions 120OR may have a first width W1 (see FIG. 7A) in the first direction (X-direction). The openings 119OP may have a second width W2 in the first direction (X-direction). In order to precisely arrange bonding wire structures 150 on the bonding pads 111 disposed in the openings 119OP, the first width W1 of the open regions 120OR may be greater than the second width W2 of the openings 119OP.

According to an embodiment of the disclosure, the center open region RH may be recessed in the solder resist layer 120 and the passivation layer 119, such that the upper pads 113 may be exposed (see FIG. 7A). An inner wall of the center open region RH may include internal side surfaces of the solder resist layer 120 and internal side surfaces of the passivation layer 119. The controller 140 and the underfill portion 180 may be disposed in the center open region RH, and the center open region RH may serve as a dam structure to control a flow of the underfill portion 180. Accordingly, the flow of the underfill portion 180 may be controlled, thereby resolving an issue in which the underfill portion 180 comes into contact with the at least one pair of chip structures 130, and improving the reliability of the semiconductor package 1000A.

A size and shape of the center open region RH may vary depending on a size and shape of the controller 140 mounted in the center open region RH. For example, when the controller 140 has a rectangular shape, the shape of the center open region RH may also have a rectangular shape, corresponding to the rectangular shape of the controller 140. A side surface of the controller 140 may be disposed to be spaced apart from the inner wall of the center open region RH by a predetermined distance. The at least one pair of chip structures 130 may be disposed on the solder resist layer 120, included in the center open region RH. In example embodiments in which the at least one pair of chip structures 130 are stacked, the number and positioning of the stacked semiconductor chips is not limited, and may vary depending on the example embodiments.

Referring to FIG. 1, the solder resist layer 120 may include a first region surrounding a portion of a side surface of the controller 140, and a second region extending to at least one side of the first region, the second region corresponding to a lower area of the at least one pair of chip structures 130. An area of the second region may be equal to or greater than a planar area of a lowermost chip of the at least one pair of chip structures 130. The first open regions 120OR1 may be disposed between the second region and the first side 110S1, and the first bonding pads 111A may be disposed in the first open regions 120OR1. Similarly, the second open regions 120OR2 may be disposed between the second region and the second side 110S2, and the second bonding pads 111B may be disposed in the second open regions 120OR2.

Referring to FIGS. 1 and 2A, a first distance D1 may refer to a distance in the first direction (X-direction) between a side surface of the controller 140 and a side surface of the solder resist layer 120. A second distance D2 may refer to a distance in the first direction (X-direction) between the side surface of the controller 140 and a side surface of the passivation layer 119. A third distance D3 may refer to a distance in the first direction (X-direction) between the side surface of the controller 140 and the first chip structure 130A or the second chip structure 130B. A fourth distance D4 may refer to a distance in the first direction (X-direction) between the internal side surfaces of the solder resist layer 120, included in the inner wall of the center open region RH. A fifth distance D5 may refer to a distance in the first direction (X-direction) between the internal side surfaces of the passivation layer 119, included in the inner wall of the center open region RH. The first distance D1 may be about 100 μm or more, for example, 100 μm to 200 μm, 100 μm to 150 μm, or 100 μm to 120 μm. When the first distance D1 is less than 100 μm, a contact height between the underfill portion 180 and the solder resist layer 120 may increase, such that the at least one pair of chip structures 130 and the underfill portion 180 may come into contact with each other.

The third distance D3 between the side surface of the controller 140 and the first chip structure 130A or the second chip structure 130B may be about 1 to 1.2 times the first distance D1 in the first direction (X-direction) between the side surface of the controller 140 and the side surface of the solder resist layer 120. When the third distance D3 is less than 1 times the first distance D1, a distance between the first and second chip structures 130A and 130B and the side surface of the controller 140 may relatively decrease, such that the first and second chip structures 130A and 130B and the underfill portion 180 may come into contact with each other. When the third distance D3 is greater than 1.2 times the first distance D1, the distance between the first and second chip structures 130A and 130B and the side surface of the controller 140 may relatively increase, which may result in an increase in a chip-mounting area and, consequently, an increase in a size of the semiconductor package.

A distance between the first chip structure 130A and the second chip structure 130B may be about 1 to 1.2 times the distance D4 between the internal side surfaces of the solder resist layer 120, included in the center open region RH.

When the distance between the first chip structure 130A and the second chip structure 130B is less than 1 times the distance between the internal side surfaces of the solder resist layer 120, the distance between the first and second chip structures 130A and 130B and the side surfaces of the controller 140 may relatively decrease, such that the first and second chip structures 130A and 130B may come into contact with the underfill portion 180. When the distance between the first chip structure 130A and the second chip structure 130B is greater than 1.2 times the distance between the internal side surfaces of the solder resist layer 120, the distance between the first and second chip structures 130A and 130B and the side surface of the controller 140 may relatively increase, which may result in an increase in a chip-mounting area and, consequently, an increase in a size of the semiconductor package.

The first distance D1 in the first direction (X-direction) between the side surface of the controller 140 and the side surface of the solder resist layer 120 may be about 1.8 to 2.2 times the second distance D2 in the first direction (X-direction) between the side surface of the controller 140 and the side surface of the passivation layer 119.

The first distance D1 in the first direction (X-direction) between the side surface of the controller 140 and the side surface of the solder resist layer 120 may be inversely proportional to the third distance D3 in the first direction (X-direction) between the side surface of the controller 140 and the first chip structure 130A or the second chip structure 130B. For example, when the underfill portion 180, disposed in the center open region RH, has a predetermined volume, an increase in the first distance D1 may result in a decrease in a height at which the underfill portion 180 is in contact with the internal side surfaces of the solder resist layer 120. Accordingly, even when the first and second chip structures 130A and 130B are disposed to be relatively close to the controller 140, the first and second chip structures 130A and 130B may not come into contact with the underfill portion 180. Accordingly, when the first distance D1 increases, the third distance D3 may decrease. As the third distance D3 decreases, a chip-mounting area may be reduced, and a size of the semiconductor package may be reduced.

Similarly, the second distance D2 in the first direction (X-direction) between the side surface of the controller 140 and the side surface of the passivation layer 119 may be inversely proportional to the third distance D3 in the first direction (X-direction) between the side surface of the controller 140 and the first chip structure 130A or the second chip structure 130B. For example, when the underfill portion 180, disposed in the center open region RH, has a predetermined volume, an increase in the second distance D2 may result in a decrease in a height at which the underfill portion 180 is in contact with the internal side surfaces of the solder resist layer 120. Accordingly, even when the first and second chip structures 130A and 130B are disposed to be relatively close to the controller 140, the first and second chip structures 130A and 130B may not come into contact with the underfill portion 180. Accordingly, as the second distance D2 increases, the third distance D3 may decrease. As the third distance D3 decreases, a chip-mounting area may be reduced, and a size of the semiconductor package may be reduced.

The center open region RH, including the internal side surfaces of the solder resist layer 120 and the internal side surfaces of the passivation layer 119, may be defined, in part, by the fourth distance D4 and the fifth distance D5. The fourth distance D4 may refer to a distance in the first direction (X-direction) between the internal side surfaces of the solder resist layer 120, opposing each other. The fifth distance D5 may refer to a distance in the first direction (X-direction) between the internal side surfaces of the passivation layer 119, opposing each other. The fourth distance D4 may be greater than the fifth distance D5.

The at least one pair of chip structures 130 may include a first chip structure 130A and a second chip structure 130B respectively including a plurality of semiconductor chips. A distance between a lowermost first semiconductor chip a1, among a plurality of first semiconductor chips a1, a2, a3, and a4 of the first chip structure 130A, and a lowermost second semiconductor chip b1, among a plurality of second semiconductor chips b1, b2, b3, and b4 of the second chip structure 130B, may be inversely proportional to the fourth distance D4 in the first direction (X-direction) between the internal side surfaces of the solder resist layer 120. For example, when the underfill portion 180, disposed in the center open region RH, has a predetermined volume, an increase in the fourth distance D4 may result in a decrease in a height at which the underfill portion 180 is in contact with the internal side surfaces of the solder resist layer 120. Accordingly, even when the first and second chip structures 130A and 130B are disposed to be relatively close to the controller 140, the first and second chip structures 130A and 130B may not come into contact with the underfill portion 180. Accordingly, when the fourth distance D4 increases, the distance between the lowermost first semiconductor chip a1, among the plurality of first semiconductor chips a1, a2, a3, and a4 of the first chip structure 130A, and the lowermost second semiconductor chip b1, among the plurality of second semiconductor chips b1, b2, b3, and b4 of the second chip structure 130B, may decrease. As the distance between the lowermost first and second semiconductor chips a1 and b1 of the at least one pair of chip structures 130 decreases, a chip-mounting area may be reduced, and a size of the semiconductor package may be reduced.

Similarly, the distance between the lowermost first semiconductor chip a1, among the plurality of first semiconductor chips a1, a2, a3, and a4 of the first chip structure 130A, and the lowermost second semiconductor chip b1, among the plurality of second semiconductor chips b1, b2, b3, and b4 of the second chip structure 130B, may be inversely proportional to the fifth distance D5 in the first direction (X-direction) between the internal side surfaces of the passivation layer 119.

The solder resist layer 120 (or a “second solder resist layer”) may include a material, the same as or similar to that of the passivation layer 119, but the disclosure is not limited thereto. For example, the solder resist layer 120 may be a photoimageable solder resist including a photoimageable resin composition. The solder resist layer 120 may be formed using a screen-printing method, a roll coating method, a curtain cotton method, and a spraying method, but the disclosure is not limited thereto. For example, when the photoimageable solder resist is a dry film, the solder resist layer 120 may be formed using a film lamination technique.

The at least one pair of chip structures 130 may be disposed on the solder resist layer 120 to be spaced apart from each other in the first direction (X-direction). The at least one pair of chip structures 130 may include a plurality of semiconductor chips including pads respectively disposed on upper surfaces thereof. For example, the at least one pair of chip structures 130 may include the first chip structure 130A disposed on the solder resist layer 120 to be adjacent to the first side 110S1, and the second chip structure 130B disposed on the solder resist layer 120 to be adjacent to the second side 110S2. The first chip structure 130A may include the plurality of first semiconductor chips a1, a2, a3, and a4 including first pads 131A respectively disposed on upper surfaces thereof, and the second chip structure 130B may include the plurality of second semiconductor chips b1, b2, b3, and b4 including second pads 131B respectively disposed on upper surfaces thereof. Respective ones of the plurality of first semiconductor chips a1, a2, a3, and a4 and the plurality of second semiconductor chips b1, b2, b3, and b4 may be attached to each other using an adhesive film, such as a die attach film (DAF).

The plurality of first semiconductor chips a1, a2, a3, and a4 may be stacked with an offset in a first horizontal direction (for example, one direction along an X-axis) such that the first pads 131A are exposed while being adjacent to the first side 110S1, and the plurality of second semiconductor chips b1, b2, b3, and b4 may be stacked with an offset in a second horizontal direction (for example, a direction, opposite to the first horizontal direction) such that the second pads 131B are exposed while being adjacent to the second side 110S2.

A distance between a lower portion of the first chip structure 130A and a lower portion of the second chip structure 130B may be greater than a distance between an upper portion of the first chip structure 130A and an upper portion of the second chip structure 130B.

A distance in the first direction (X-direction) between the lowermost first semiconductor chip a1 of the plurality of first semiconductor chips a1, a2, a3, and a4 and the lowermost second semiconductor chip b1 of the plurality of second semiconductor chips b1, b2, b3, and b4 may be greater than a distance in the first direction (X-direction) between side surfaces of the solder resist layer 120.

The controller 140, controlling the plurality of first semiconductor chips a1, a2, a3, and a4 and the plurality of second semiconductor chips b1, b2, b3, and b4, may be disposed between the first chip structure 130A and the second chip structure 130B.

Referring to FIG. 1, the at least one pair of chip structures 130 may be disposed to overlap at least a portion of each of the passivation layer 119 and the solder resist layer 120 in the vertical direction (Z-direction). According to an example embodiment of the disclosure, the at least one pair of chip structures 130 may be disposed on the solder resist layer 120, such that a distance between the at least one pair of chip structures 130 and the controller 140 may decrease. As the distance between the controller 140 and the at least one pair of chip structures 130 decreases, a chip-mounting area may be reduced, and a size of the semiconductor package may be reduced. Accordingly, upper first semiconductor chips a2, a3, and a4 on lowermost first semiconductor chip a1, and upper second semiconductor chips b2, b3, and b4 on lowermost second semiconductor chip b1, may be disposed to overlap at least a portion of the controller 140 in the vertical direction (Z-direction). For example, among the respective pluralities of first semiconductor chips a1, a2, a3, and a4, and second semiconductor chips b1, b2, b3, and b4, first chip a2 and second chip b2 may be disposed to overlap at least a portion of the controller 140 in the vertical direction (Z-direction), and first chip a3 and second chip b3 may be disposed to overlap at least a portion of the controller 140 in the vertical direction (Z-direction).

Each of the first chip structure 130A and the second chip structure 130B may be disposed on the solder resist layer 120 to be spaced apart from each other in the first direction (X-direction) with the controller 140 interposed therebetween. For example, the lowermost first semiconductor chip a1, among the plurality of first semiconductor chips a1, a2, a3, and a4, may be disposed to be spaced apart from the side surface of the controller 140 by the third distance D3 in the first direction (X-direction). Similarly, the lowermost second semiconductor chip b1, among the plurality of second semiconductor chips b1, b2, b3, and b4, may be disposed to be spaced apart from the side surface of the controller 140 by the third distance D3 in the first direction (X-direction).

The plurality of first semiconductor chips a1, a2, a3, and a4, and the plurality of second semiconductor chips b1, b2, b3, and b4 may include a non-volatile memory semiconductor chips such as flash memory, phase-change random access memory (PRAM), magnetoresistive random-access memory (MRAM), ferroelectric random access memory (FeRAM), or resistive random access memory (RRAM), and/or a volatile memory semiconductor chip such as dynamic random access memory (DRAM) or static random access memory (SRAM).

The controller 140 may be disposed between the at least one pair of chip structures 130, spaced apart from each other in the first direction (X-direction). The controller 140 may have an active surface 140A on which the connection pads 141 are disposed, and an inactive surface 140N opposite the active surface. The connection pads 141, disposed on the active surface 140A of the controller 140, may be electrically connected to the upper pads 113 through the connection structure 160. The controller 140 may be electrically connected to the at least one pair of chip structures 130 through the connection structure 160, the interconnection circuits 117, the bonding pads 111, and the bonding wire structures 150.

The controller 140 may include a control circuit for the first chip structure 130A and the second chip structure 130B. The controller 140 may include a memory controller, determining a data-processing order of a plurality of memory chips and preventing errors and defective sections.

The underfill portion 180 may be disposed between the controller 140 and the substrate 110. The underfill portion 180 may surround a portion of each of the connection structures 160, between the controller 140 and the substrate 110, and may fill a space between the side surface of the controller 140, the side surface of the solder resist layer 120, and a side surface of the solder mask layer 119.

The underfill portion 180 may include a surface extending from the side surface of the controller 140 to the side surface of the solder resist layer 120, and the surface may be spaced apart from a side surface of each of the first chip structure 130A and the second chip structure 130B. The underfill portion 180 may be in contact with a portion of the side surface of the solder resist layer 120.

The underfill portion 180 may be formed using an insulating resin such as an epoxy resin. The underfill portion 180 may have a capillary underfill (CUF) structure, but the disclosure is not limited thereto. In some example embodiments, the underfill portion 180 may have a mold underfill (MUF) structure integrated with the solder resist layer 120, the at least one pair of chip structures 130, the controller 140, and the encapsulant 170 covering the underfill portion 180.

The bonding wire structures 150 may include a first bonding wire structure 150A connecting the first pads 131A of the first chip structure 130A to the first bonding pads 111A, and a second bonding wire structure 150B connecting the second pads 131B of the second chip structure 130B to the second bonding pads 111B. The bonding wire structures 150 may extend from the first chip structure 130A and the second chip structure 130B toward the first side 110S1 and the second side 110S2, respectively, and may be electrically connected to the interconnection circuits 117 of the substrate 110.

The connection structure 160 (or a “solder structure”) may electrically connect the connection pads 141 of the controller 140 to the upper pads 113 of the substrate 110. The connection structure 160 may include a material, the same as or similar to that of the connection bumps 115BP, but the disclosure is not limited thereto. For example, the connection structure 160 may include tin (Sn) or an alloy (for example, Sn—Ag—Cu) including tin (Sn).

The encapsulant 170 may protect the chip structure 130 and the controller 140 from external environments such as physical impact, moisture, or the like. The encapsulant 170 may include an insulating material, for example, an epoxy molding compound (EMC). The encapsulant 170 may be in contact with a portion of the side surface of the solder resist layer 120. At least one of the at least one pair of chip structures 130 may be spaced apart from the underfill portion 180 by the encapsulant 170. The encapsulant 170 may be disposed on the substrate 110, and may surround a side surface of the at least one of the at least one pair of chip structures 130, a portion of the side surface of the controller 140, and an upper surface of the underfill portion 180. Here, the upper surface of the underfill portion 180 may refer to a surface extending from the side surface of the controller 140 to the side surface of the solder resist layer 120.

Referring to FIG. 2B, the solder resist layer 120 on which the at least one pair of chip structures 130 are not disposed may form a dam structure. A width (sixth distance) D6 of the solder resist layer 120, forming the dam structure, may be within a range of about 50 μm to about 250 μm. The first to sixth distances D1, D2, D3, D4, D5, and D6 in the second direction (Y-direction) of FIG. 2B may be the same as the first to sixth distances D1, D2, D3, D4, D5, and D6 in the first direction (X-direction) of FIG. 2A, respectively.

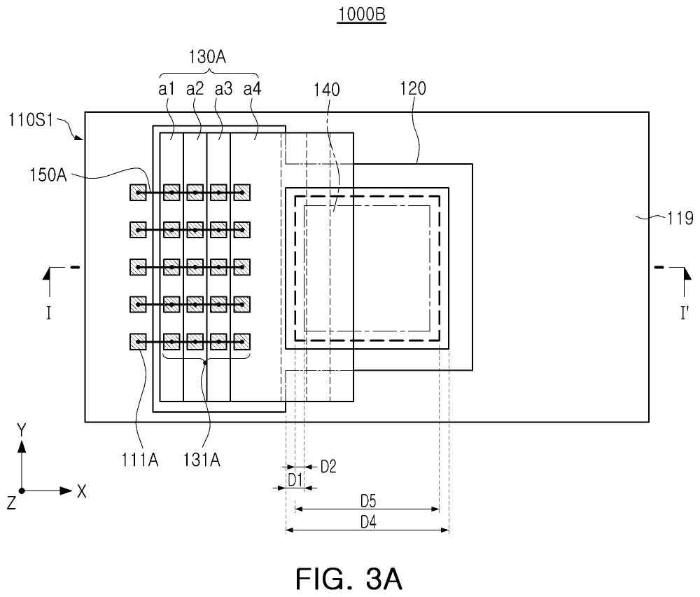

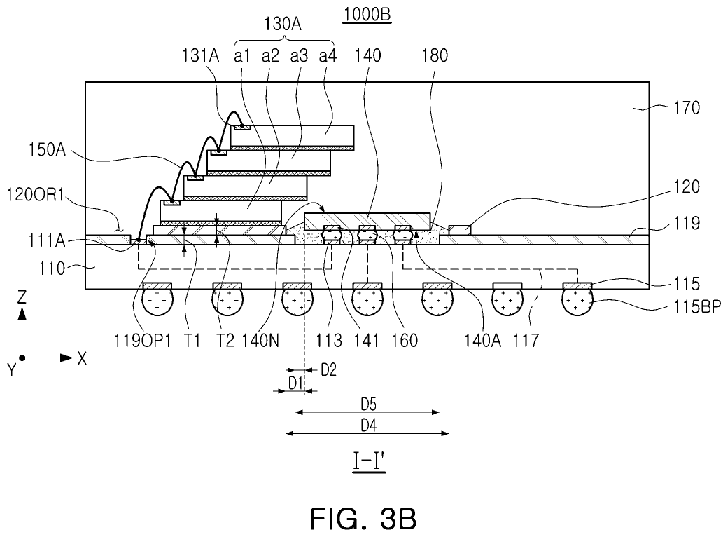

FIG. 3A is a schematic plan view of a semiconductor package 1000B according to example embodiments. FIG. 3B is a schematic cross-sectional view of the semiconductor package 1000B according to example embodiments. FIG. 3B is a cross-sectional view taken along line I-I′ of FIG. 3A. FIGS. 3A and 3B illustrate regions corresponding to FIGS. 1 and 2A, respectively.

Referring to FIGS. 3A and 3B, a semiconductor package 1000B according to an example embodiment may have features the same as or similar to those described with reference to FIGS. 1, 2A, and 2B, except that FIGS. 3A and 3B only include at least one chip structure 130A instead of the at least one pair of chip structures 130 in FIGS. 1, 2A, and 2B.

Referring to FIG. 3A, a solder resist layer 120 may include a first region surrounding a portion of a side surface of a controller 140, and a second region extending to at least one side of the first region, the second region corresponding to a lower area of the at least one chip structure 130A. An area of the second region may be equal to or greater than a planar area of the lowermost chip a1 of the at least one chip structure 130A. First open regions 120OR1 may be disposed between the second region and a first side 110S1, and first bonding pads 111A may be disposed in the first open regions 120OR1. The first open regions 120OR1 and a center open region RH (see FIG. 7A) may surround a portion of a side surface of the second region.

The at least one chip structure 130A may be disposed to be spaced apart from the controller 140 by the third distance D3 of FIG. 2A. The at least one chip structure 130A may include a plurality of semiconductor chips a1, a2, a3, and a4 stacked in a vertical direction (Z-direction). For example, in the same manner as the plurality of first semiconductor chips a1, a2, a3, and a4 of FIG. 2A, the plurality of semiconductor chips a1, a2, a3, and a4 of FIG. 3B may be stacked with an offset in a first horizontal direction (for example, one direction along an X-axis) such that first pads 131A are adjacent to the first side 110S1, but the disclosure is not limited thereto. A shape in which the plurality of semiconductor chips a1, a2, a3, and a4 are stacked and the number thereof may not be limited, and may vary depending on example embodiments.

The number of the at least one chip structures 130A, disposed on the solder resist layer 120, may not be determined as one, and the number of the at least one chip structures 130A disposed may vary depending on example embodiments. For example, three or more chip structures 130A may be disposed on the solder resist layer 120 to be adjacent to the controller 140. Accordingly, a shape of the solder resist layer 120 may vary depending on an arrangement state of the at least one chip structure 130A.

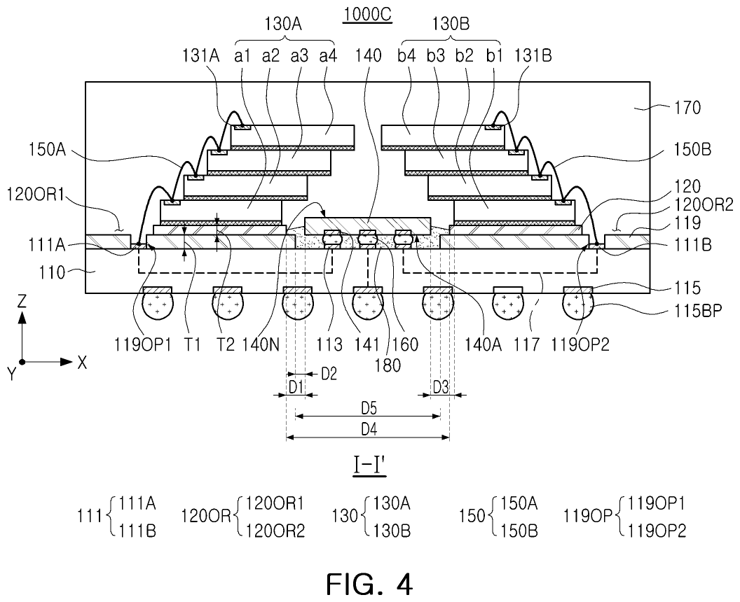

FIG. 4 is a schematic cross-sectional view of a semiconductor package 1000C according to an example embodiment. FIG. 4 illustrates a region corresponding to FIG. 2A.

Referring to FIG. 4, the semiconductor package 1000C according to an example embodiment may have features the same as or similar to those described with reference to FIGS. 1, 2A, and 2B, except that a thickness of a passivation layer 119 is greater than that of a solder resist layer 120.

The passivation layer 119 may be formed by coating the entirety of a top surface of the substrate 110 with a liquid solder resist material using a screen-printing method or by bonding a film-type solder resist material using a laminating method. When the liquid solder resist material is used, the passivation layer 119 may be formed to have a thickness, relatively greater than that of the solder resist layer 120. The thickness of the passivation layer 119 may be within a range of about 10 μm to about 18 μm.

When the thickness of the passivation layer 119 increases, an internal space of a center open region RH may also increase, while a height at which an underfill portion 180 in the center open region RH is in contact with the solder resist layer 120 may decrease. Accordingly, at least one pair of chip structures 130 may be disposed to be relatively closer to a controller 140, and a size of the semiconductor package may be reduced.

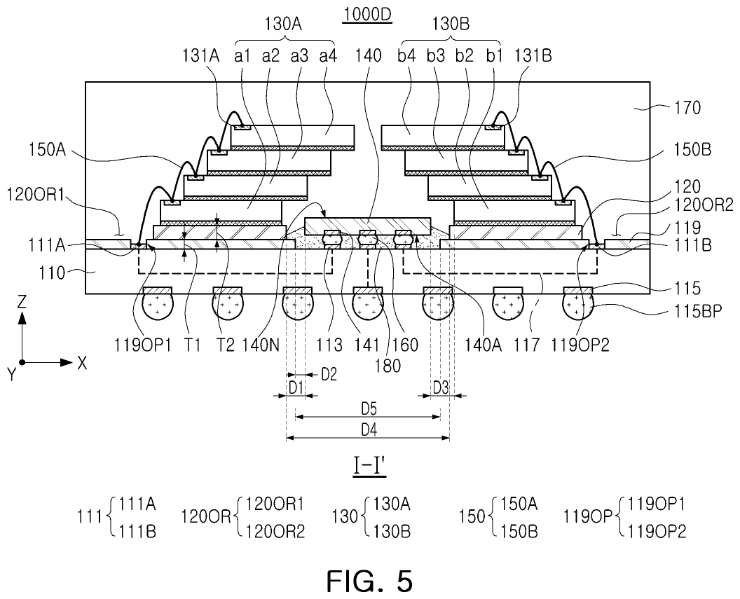

FIG. 5 is a schematic cross-sectional view of a semiconductor package 1000D according to an example embodiment. FIG. 5 illustrates a region corresponding to FIG. 2A.

Referring to FIG. 5, the semiconductor package 1000D according to an example embodiment may have features the same as or similar to those described with reference to FIGS. 1, 2A and 2B, except that a thickness of a solder resist layer 120 is greater than that of a passivation layer 119.

The solder resist layer 120 may be formed by bonding a film-type solder resist material using a laminating method. When the film-type solder resist material is used, high precision and uniform thickness control may be achieved, thereby forming a fine pattern. The thickness of the solder resist layer 120 may be within a range of about 10 μm to about 18 μm.

When the thickness of the solder resist layer 120 increases, an internal space of a center open region RH may also increase, while a height at which an underfill portion 180 in the center open region RH is in contact with the solder resist layer 120 may decrease. Accordingly, the at least one pair of chip structures 130 may be disposed to be relatively closer to a controller 140, and a size of the semiconductor package may be reduced.

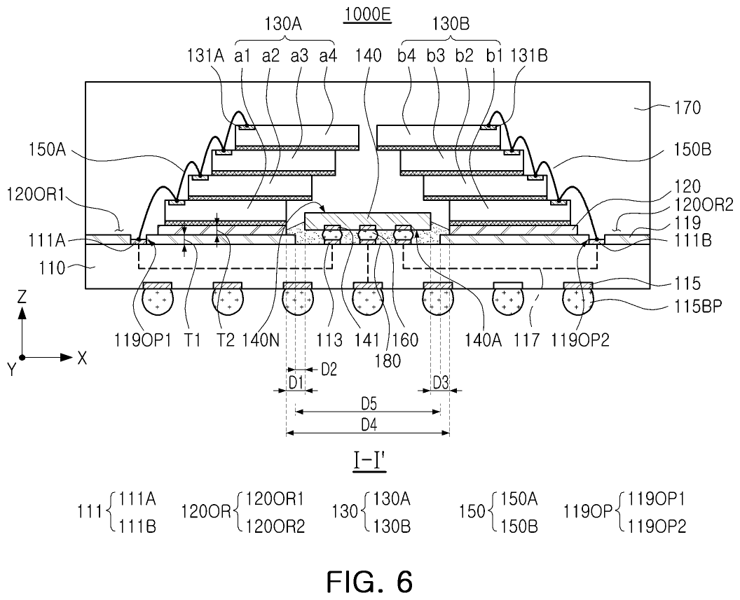

FIG. 6 is a schematic cross-sectional view of a semiconductor package 1000E according to an example embodiment. FIG. 6 illustrates a region corresponding to FIG. 2A.

Referring to FIG. 6, the semiconductor package 1000E according to an example embodiment may have features the same as or similar to those described with reference to FIGS. 1, 2A, and 2B, except that side surfaces of at least one pair of chip structures 130 are coplanar with internal side surfaces of a solder resist layer 120. When the side surfaces of the at least one pair of chip structures 130 are coplanar with the internal side surfaces of the solder resist layer 120, a distance between a controller 140 and the at least one pair of chip structures 130 may decrease, and thus a size of the semiconductor package may be reduced.

A side surface of a lowermost first semiconductor chip a1, among a plurality of first semiconductor chips a1, a2, a3, and a4, and a side surface of a lowermost second semiconductor chip b1, among a plurality of second semiconductor chips b1, b2, b3, and b4, may be coplanar with a side surface of the solder resist layer 120.

A distance between a first chip structure 130A and a second chip structure 130B may be equal to a distance between the internal side surfaces of the solder resist layer 120, included in a center open region RH.

A third distance D3 between a side surface of the controller 140 and the first chip structure 130A or the second chip structure 130B of FIG. 6 may be equal to a first distance D1 in a first direction (X-direction) between the side surface of the controller 140 and the side surface of the solder resist layer 120.

The first and second chip structures 130A and 130B may include, respectively, a plurality of first semiconductor chips a1, a2, a3, and a4 and a plurality of second semiconductor chips b1, b2, b3, and b4, stacked in a vertical direction (Z-direction), wherein a lowermost first semiconductor chip a1 among the plurality of first semiconductor chips a1, a2, a3, and a4, and a lowermost second semiconductor chip b1 among the plurality of second semiconductor chips b1, b2, b3, and b4, may be spaced apart from the side surface of the controller 140 by a distance in the first direction (X-direction) equal to the first distance D1 or the third distance D3 between the side surface of the controller 140 and the first and second chip structures 130A and 130B.

Hereinafter, a method of manufacturing a semiconductor package according to an example embodiment of the disclosure will be described.

FIGS. 7A, 7B, 7C, and 7D are schematic cross-sectional views of a method of manufacturing the semiconductor package 1000A according to example embodiments. FIGS. 7A to 7D illustrate cross-sections corresponding to FIG. 2A.

Referring to FIG. 7A, a solder mask layer 119 and a resist layer 120 may be formed on a substrate 110.

The solder mask layer 119 may be formed using a first solder resist. The first solder resist may be coated on the substrate 110 using a screen-printing method. The first solder resist may be a solder resist including an epoxy resin or a polyurethane resin. In some example embodiments, the first solder resist may include a photoimageable resin, and may be in a liquid or dry film form. When the first solder resist is in a liquid form, the first solder resist may be coated on the substrate 110 using the screen-printing method. When the first solder resist is in a dry film form, the first solder resist may be formed on the substrate 110 using a film lamination method.

The solder resist layer 120 may be formed using a second solder resist. The second solder resist may be a photoimageable solder resist including a photoimageable resin composition, and may be in a liquid or dry film form. When the second solder resist is in a liquid form, the second solder resist may be coated on the solder mask layer 119 using the screen-printing method. When the second solder resist is in a film form, the second solder resist may be formed on the solder mask layer 119 using the film lamination method. A thickness of the formed solder resist layer 120 may be within a range of about 10 μm to about 18 μm, and a thickness of the formed solder mask layer 119 may be within a range of about 10 μm to about 18 μm.

The solder resist layer 120 may have a first open region 120OR1 on a first side 110S1 of the substrate 110, and a second open region 120OR2 on a second side 110S2 of the substrate 110. In this case, the first open region 120OR1 and the second open region 120OR2 may be formed such that the solder mask layer 119, disposed on first bonding pads 111A and second bonding pads 111B, is exposed in a first direction (X-direction). A first width W1 of open regions 120OR in the first direction (X-direction) may be formed to have a horizontal width, greater than a second width W2 of openings 119OP in the first direction (X-direction).

The solder mask layer 119 may have first openings 119OP1 adjacent to the first side 110S1 of the substrate 110, and second openings 119OP2 adjacent to the second side 110S2. In this case, the first opening 119OP1 and the second opening 119OP2 may be formed to expose upper surfaces of the first bonding pads 111A and upper surfaces of the second bonding pads 111B.

The solder resist layer 120 may form a center open region RH, between the first open region 120OR1 and the second open region 120OR2. The center open region RH may include a first region passing through the solder mask layer 119, and a second region passing through the solder resist layer 120. A width of the second region may be greater than that of the first region.

The first open region 120OR1, the second open region 120OR2, and the second region of the center open region RH1 and the first opening 119OP1, the second opening 119OP2, and the first region of the center open region RH may be simultaneously formed or sequentially formed. For example, when the solder resist layer 120 and the solder mask layer 119 include a photoimageable material, the solder resist layer 120 and the solder mask layer 119 may be formed sequentially or simultaneously using a photolithography process. When the solder resist layer 120 and the solder mask layer 119 include different materials, the solder resist layer 120 and the solder mask layer 119 may be formed sequentially.

Referring to FIG. 7B, a controller 140 may be mounted on an upper surface of the substrate 110. The controller 140 may be mounted on the substrate 110 in a flip-chip bonding manner. Specifically, the controller 140 may be mounted on the substrate 110 by performing a thermal-compression bonding process. An underfill portion 180, surrounding a connection structure 160, may be formed using the thermal-compression bonding process.

The controller 140 and the underfill portion 180 may be disposed in the center open region RH of FIG. 7A, and the center open region RH may serve as a dam structure to control a flow of the underfill portion 180. Accordingly, the flow of the underfill portion 180 may be controlled, thereby resolving an issue in which the underfill portion 180 comes into contact with at least one pair of chip structures 130, and improving the reliability of the semiconductor package 1000A.

Referring to FIG. 7C, a first chip structure 130A and a second chip structure 130B may be disposed on the solder resist layer 120 at both sides of the controller 140. The first chip structure 130A and the second chip structure 130B may be attached to an upper surface of the solder resist layer 120 using an adhesive film attached to a lower portion thereof. The first chip structure 130A may include a plurality of first semiconductor chips a1, a2, a3, and a4 including first pads 131A respectively disposed on upper surfaces thereof, and the second chip structure 130B may include a plurality of second semiconductor chips b1, b2, b3, and b4 including second pads 131B respectively disposed on upper surfaces thereof. The plurality of first semiconductor chips a1, a2, a3, and a4 may be stacked with an offset such that the first pads 131A are adjacent to the first side 110S1, and the plurality of second semiconductor chips b1, b2, b3, and b4 may be stacked with an offset such that the second pads 131B are adjacent to the second side 110S2.

Referring to FIG. 7D, a first bonding wire structure 150A, connecting the first pads 131A to a first bonding pad 111A, and a second bonding wire structure 150B, connecting the second pads 131B to a second bonding pad 111B, may be formed. Thereafter, an encapsulant (170 of FIG. 2A) and connection bumps (115BP of FIG. 2A) may be formed.

According to an aspect of an example embodiment, a method of manufacturing a semiconductor package, may include: forming pads on a substrate by forming first bonding pads adjacent a first side of the substrate, and forming second bonding pads adjacent a second side of the substrate opposing the first side; forming upper pads on the substrate between the first bonding pads and the second bonding pads; forming a solder mask layer exposing the pads at an upper portion of the substrate; forming a solder resist layer on the solder mask layer, the solder resist layer and the solder mask layer defining a center open region exposing the upper pads; mounting a controller in the center open region, the mounting the controller including forming connection pads at a lower portion of the controller, and forming connection structures electrically connecting the connection pads to the upper pads; disposing a first chip structure on the solder resist layer adjacent the first side, and electrically connecting the first chip structure to the first bonding pads; disposing a second chip structure on the solder resist layer adjacent the second side, and electrically connecting the second chip structure to the second bonding pads; and forming an underfill portion surrounding a portion of each of the connection structures between the controller and the substrate, the forming the underfill portion including filling a space defined by a side surface of the controller, a side surface of the solder resist layer, and a side surface of the solder mask layer, wherein a distance between the first chip structure and the second chip structure is about 1 to about 1.2 times a distance between inner side surfaces of the solder resist layer defining the center open region.

The forming the underfill portion may include flowing the underfill portion into the center open region.

The underfill portion may be physically distanced from at least one of the first chip structure or the second chip structure.

The forming the solder resist layer may include depositing a first region of the solder resist layer surrounding a portion of the side surface of the controller, and depositing a second region of the solder resist layer extending to at least one side of the first region, the second region corresponding to a lower area of at least one of the first chip structure or the second chip structure.

The disposing the first chip structure may include stacking a plurality of first semiconductor chips overlapping in a vertical direction, and the disposing the second chip structure may include stacking a plurality of second semiconductor chips overlapping in the vertical direction, and a side surface of a lowermost first semiconductor chip, among the plurality of first semiconductor chips, and a side surface of a lowermost second semiconductor chip, among the plurality of second semiconductor chips, may be coplanar with the side surface of the solder resist layer.

According to example embodiments of the disclosure, a semiconductor package may have a reduced size and improved reliability.

While example embodiments have been shown and described above, it will be apparent to those skilled in the art that modifications and variations could be made without departing from the scope of the present disclosure as defined by the appended claims.

What is claimed is:

1. A semiconductor package comprising:
a substrate having a first side and a second side opposing each other, wherein the substrate comprises pads and a solder mask layer exposing the pads at an upper portion of the substrate, and the pads comprise first bonding pads adjacent the first side, second bonding pads adjacent to the second side, and upper pads between the first bonding pads and the second bonding pads;
a solder resist layer on the solder mask layer;
a first chip structure on the solder resist layer adjacent to the first side, the first chip structure electrically connected to the first bonding pads;
a second chip structure on the solder resist layer adjacent to the second side, the second chip structure electrically connected to the second bonding pads;
a controller between the first chip structure and the second chip structure, the controller comprising connection pads at a lower portion of the controller;
connection structures electrically connecting the connection pads and the upper pads to each other; and
an underfill portion surrounding a portion of each of the connection structures, between the controller and the substrate, the underfill portion filling a space defined by a side surface of the controller, a side surface of the solder resist layer, and a side surface of the solder mask layer,
wherein the solder resist layer and the solder mask layer have a center open region exposing the upper pads, and
wherein a distance between the first chip structure and the second chip structure is about 1 to about 1.2 times a distance between inner side surfaces of the solder resist layer defining the center open region.

2. The semiconductor package of claim 1, wherein the solder resist layer overlaps at least a portion of each of the first chip structure and the second chip structure in a vertical direction.

3. The semiconductor package of claim 1, wherein a thickness of the solder resist layer is within a range of about 10 μm to about 18 μm.

4. The semiconductor package of claim 1, wherein the underfill portion comprises a surface extending from the side surface of the controller to the side surface of the solder resist layer, and spaced apart from a side surface of each of the first chip structure and the second chip structure.

5. The semiconductor package of claim 1, wherein the first chip structure comprises a plurality of first semiconductor chips comprising first pads respectively at upper surfaces of the plurality of first semiconductor chips,
wherein the second chip structure comprises a plurality of second semiconductor chips comprising second pads respectively at upper surfaces thereof,
wherein the plurality of first semiconductor chips are stacked with an offset in a first horizontal direction such that the first pads are exposed adjacent the first side,
wherein the plurality of second semiconductor chips are stacked with an offset in a second horizontal direction such that the second pads are exposed adjacent the second side, and
wherein a distance between a lower portion of the first chip structure and a lower portion of the second chip structure is greater than a distance between an upper portion of the first chip structure and an upper portion of the second chip structure.

6. The semiconductor package of claim 5, further comprising:
a first bonding wire structure connecting the first pads and the first bonding pads to each other; and
a second bonding wire structure connecting the second pads and the second bonding pads to each other.

7. The semiconductor package of claim 1, wherein the first chip structure comprises a plurality of first semiconductor chips stacked to overlap in a vertical direction, and the second chip structure comprises a plurality of second semiconductor chips stacked to overlap in the vertical direction, and
wherein a side surface of a lowermost first semiconductor chip, among the plurality of first semiconductor chips, and a side surface of a lowermost second semiconductor chip, among the plurality of second semiconductor chips, are coplanar with the side surface of the solder resist layer.

8. The semiconductor package of claim 1, wherein the first chip structure comprises a plurality of first semiconductor chips stacked with an offset in a first horizontal direction away from the first side, and the second chip structure comprises a plurality of second semiconductor chips stacked with an offset in a second horizontal direction away from the second side, and
wherein a distance in the first horizontal direction between a lowermost first semiconductor chip, among the plurality of first semiconductor chips, and a lowermost second semiconductor chip, among the plurality of second semiconductor chips, is greater than a distance in the first horizontal direction between the inner side surfaces of the solder resist layer.

9. The semiconductor package of claim 1, wherein the solder resist layer comprises a film-type solder resist material.

10. The semiconductor package of claim 1, wherein the center open region comprises a first region passing through the solder mask layer, and a second region passing through the solder resist layer, and
wherein a width of the second region is greater than a width of the first region.

11. A semiconductor package comprising:
a substrate having a first side and a second side opposing each other, the substrate comprising edge pads, center pads, and openings exposing the edge pads and the center pads;
a solder resist layer on the solder mask layer and comprising an open region exposing the edge pads;
a controller having an active surface opposing the center pads and an inactive surface opposite to the active surface, the controller comprising connection pads on the active surface;
connection structures between the controller and the center pads of the substrate, the connection structures electrically connecting the connection pads of the controller and the center pads of the substrate to each other;
at least one chip structure disposed on the solder resist layer and spaced apart from the controller, the at least one chip structure comprising upper pads electrically connected to the edge pads; and
an underfill portion surrounding a portion of each of the connection structures, between the controller and the substrate, the underfill portion filling a space defined by a side surface of the controller, a side surface of the solder resist layer, and a side surface of the solder mask layer,
wherein the solder resist layer comprises a first region surrounding a portion of the side surface of the controller, and a second region extending to at least one side of the first region, the second region corresponding to a lower area of the at least one chip structure.

12. The semiconductor package of claim 11, wherein the at least one chip structure comprises a plurality of semiconductor chips overlapping each other in a vertical direction, and
wherein an area of the second region is equal to or greater than a planar area of a lowermost chip, among the plurality of semiconductor chips.

13. The semiconductor package of claim 11, wherein the open region is between the second region and the first side, and
wherein the edge pads are in the open region.

14. The semiconductor package of claim 11, further comprising:
a bonding wire structure connecting the edge pads of the substrate and the upper pads of the at least one chip structure to each other.

15. The semiconductor package of claim 11, wherein the at least one chip structure overlaps at least a portion of the second region and at least a portion of the controller in a vertical direction.

16. The semiconductor package of claim 11, further comprising:
an encapsulant disposed on the substrate and surrounding a side surface of the at least one chip structure, the portion of the side surface of the controller, and an upper surface of the underfill portion.

17. The semiconductor package of claim 16, wherein the encapsulant is in contact with a portion of the side surface of the solder resist layer.

18. The semiconductor package of claim 16, wherein the at least one chip structure is spaced apart from the underfill portion by the encapsulant.

19. A semiconductor package comprising:
a substrate comprising edge pads and center pads on an upper portion thereof;
a first solder resist layer on the substrate, the first solder resist layer exposing the edge pads and the center pads;
a second solder resist layer on the first solder resist layer, the second solder resist layer having a step portion with respect to the first solder resist layer;
a controller overlapping the center pads of the substrate in a vertical direction, the controller comprising connection pads at a lower portion of the controller;
at least one pair of chip structures disposed on the second solder resist layer and spaced apart from each other with the controller interposed therebetween, the at least one pair of chip structures comprising a plurality of semiconductor chips further comprising upper semiconductor chips on a lowermost semiconductor chip, and upper pads at upper surfaces of the at least one pair of chip structures;
connection structures electrically connecting the connection pads of the controller and the center pads of the substrate to each other;
a bonding wire structure electrically connecting the upper pads of each of the at least one pair of chip structures and the edge pads of the substrate to each other; and
an underfill portion surrounding a portion of each of the connection structures, between the controller and the substrate, the underfill portion filling a space defined by a side surface of the controller, a side surface of the first solder resist layer, and, of the second solder resist layer,
wherein the at least one pair of chip structures overlaps at least a portion of each of the first solder resist layer and the second solder resist layer in the vertical direction, and
wherein the upper semiconductor chips overlap at least a portion of the controller in the vertical direction.

20. The semiconductor package of claim 19, wherein the substrate further includes an interconnection circuit electrically connecting the edge pads and the center pads to each other, and
wherein the controller is electrically connected to the at least one pair of chip structures through the connection structures and the interconnection circuit.
